(19) United States
(12) Patent Application Publication
(10) Pub. No.: US 2025/0309069 A1
(43) Pub. Date: Oct. 2, 2025

(54) PACKAGED CHIP

(71) Applicant: REALTEK SEMICONDUCTOR CORP., Hsinchu (TW)

(72) Inventors: Hao-Lian Wang, Hsinchu (TW); Kuo-Chou Cheng, Hsinchu (TW)

(73) Assignee: REALTEK SEMICONDUCTOR CORP., Hsinchu (TW)

(21) Appl. No.: 19/092,048

(22) Filed: Mar. 27, 2025

(30) Foreign Application Priority Data
Mar. 29, 2024 (TW) 113112210

(51) Int. Cl. H01L 23/495; H01L 23/00

(52) U.S. Cl. CPC H01L 23/49548; H01L 23/49513; H01L 24/48; H01L 2224/48247; H01L 2924/37001

(57) ABSTRACT

A packaged chip includes a die pad and a die. The die pad includes a first sub-die pad and a second sub-die pad. The die is disposed on the die pad. The first sub-die pad and the second sub-die pad are electrically isolated. The first sub-die pad serves as a digital ground. The second sub-die pad serves as an analog ground.

### CROSS-REFERENCE TO RELATED APPLICATION

This non-provisional application claims priority under 35 U.S.C. § 119(a) to Patent Application No. 113112210 filed in Taiwan, R.O.C. on Mar. 29, 2024, the entire contents of which are hereby incorporated by reference.

### BACKGROUND

### Technical Field

The present disclosure relates to an integrated circuit package technology, and in particular to an integrated circuit package technology with an exposed pad (E-pad).

### Related Art

10G Ethernet physical layer integrated circuit wafers are used for high-speed signal transmission and are therefore sensitive to signals, so a ball grid array (BGA) package technology is preferred when selecting packages. However, the ball grid array package technology has the problems of low yield, poor heat dissipation performance and high manufacturing cost. Besides, the ball grid array package needs a substrate, so the package design cycle will be longer. Moreover, the application of the ball grid array package in a printed circuit board (PCB) requires a complicated design. In addition, it is also required to consider the working performance of the packaged wafer.

### SUMMARY

In view of this, some embodiments of the present disclosure provide a packaged chip to alleviate the problems in the prior art.

Some embodiments of the present disclosure provide a wafer, including a die pad and a die. The die pad includes a first sub-die pad and a second sub-die pad. The die is disposed on the die pad. The first sub-die pad and the second sub-die pad are electrically isolated. The first sub-die pad serves as a digital ground, and the second sub-die pad serves as an analog ground.

In some embodiments of the present disclosure, the die includes a plurality of power domains, corresponding a first power domain in the power domains of the die. The packaged chip includes at least one power bar connected with a plurality of leads corresponding to different positions of the first power domain, and each of a plurality of power bond pads corresponding to the first power domain is connected with the power bar through a bond wire.

Based on the above, according to the packaged chip provided by some embodiments of the present disclosure, by using the first sub-die pad as the digital ground of the packaged chip and the second sub-die pad as the analog ground of the packaged chip, an interference between the grounds can be reduced. In some embodiments of the present disclosure, a design of connecting at least one power bar with the plurality of leads corresponding to different positions of the first power domain can increase bonding zones for the bond wires. With the increase of the bonding zones for the bond wires, the power bond pads on the die do not need to be crowded in the same zone during position design and can be distributed uniformly, a number of the leads can be reduced, and a RLC effect is weak, so that good electrical properties and current resistance can be provided.

### BRIEF DESCRIPTION OF THE DRAWINGS

FIG. 1 is a schematic top view of a packaged chip according to an embodiment of the present disclosure; and

FIG. 2 is a schematic view of a die pad according to an embodiment of the present disclosure.

### DETAILED DESCRIPTION

The foregoing and other technical contents, features and efficacies of the present disclosure will be clearly presented in the following detailed description of embodiments with reference to the drawings. The thickness or size of each element in the drawings is exaggerated, omitted or sketched for those skilled in the art to understand and read, and the size of each element is not exactly its actual size, and is not intended to limit the applicable limit conditions of the present disclosure, so it has no technical substantive significance. Any modification of structure, change of proportion or adjustment of size shall still fall within the scope of the technical contents disclosed in the present disclosure without affecting the efficacy and objective that can be achieved by the present disclosure. The same reference numerals in all drawings will be used to denote the same or similar elements. The term “connection” mentioned in the following embodiments may refer to any direct or indirect connection means.

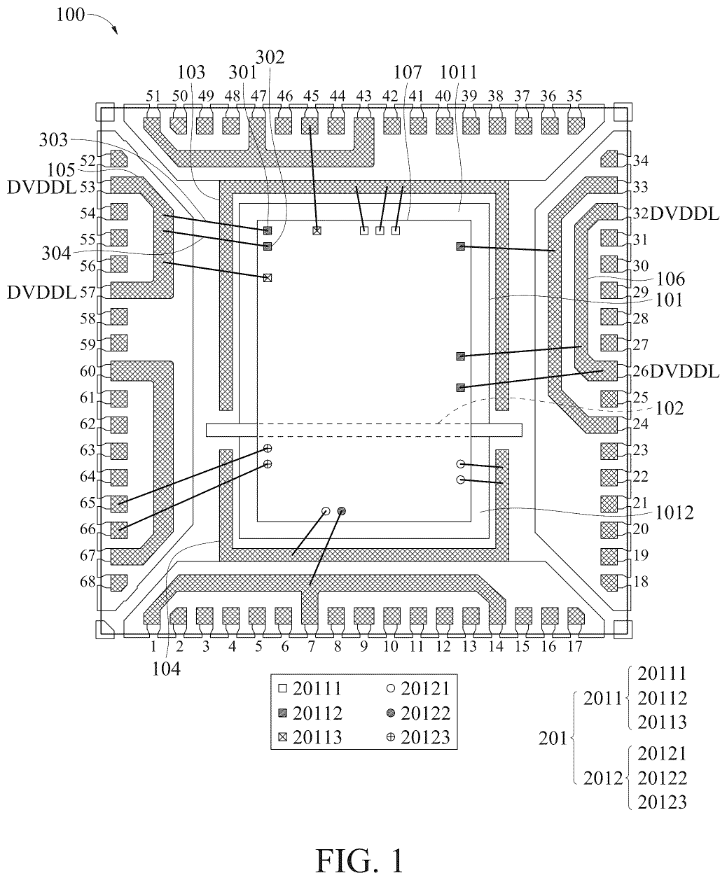

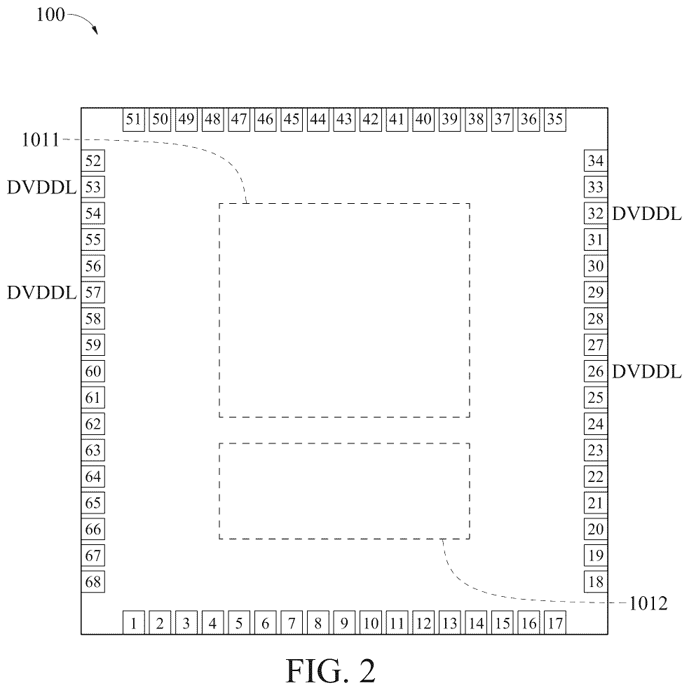

FIG. 1 is a schematic top view of a packaged chip according to an embodiment of the present disclosure. FIG. 2 is a schematic view of a die pad according to an embodiment of the present disclosure. Referring to both FIG. 1 and FIG. 2, in some embodiments of the present disclosure, the packaged chip 100 includes a die pad 101. The die pad 101 includes a first sub-die pad 1011 and a second sub-die pad 1012. The packaged chip 100 includes a die 107. The die 107 is disposed on the die pad 101. The first sub-die pad 1011 and the second sub-die pad 1012 are electrically isolated. The first sub-die pad 1011 serves as a digital ground of the packaged chip 100, and the second sub-die pad 1012 serves as an analog ground of the packaged chip 100.

In the above embodiment, by using the first sub-die pad 1011 as the digital ground of the packaged chip 100 and the second sub-die pad 1012 as the analog ground of the packaged chip 100, an interference between the grounds can be reduced.

In some embodiments of the present disclosure, the die 107 is bonded to a top surface of the die pad 101 through using an adhesive. The adhesive is, for example, a silver adhesive or an epoxy. The die pad 101 and the die 107 are packaged by a molding compound to form the packaged chip 100. In some embodiments of the present disclosure, a bottom surface of the die pad 101 (including a bottom surface of the first sub-die pad 1011 and a bottom surface of the second sub-die pad 1012) is exposed outside the molding compound of the packaged chip 100. Exposing the bottom surface of the die pad 101 (including the bottom surface of the first sub-die pad 1011 and the bottom surface of the second sub-die pad 1012) outside the molding compound of the packaged chip 100 is beneficial to dissipating heat generated during the operation of the packaged chip 100. The bottom surface of the die pad 101 (including the bottom surface of the first sub-die pad 1011 and the bottom surface of the second sub-die pad 1012) exposed outside the molding compound of the packaged chip 100 is called an exposed pad (E-pad) structure.

In application, when the packaged chip 100 is soldered to a printed circuit board (PCB), the bottom surface of the first sub-die pad 1011 is electrically connected to a digital ground layer of the printed circuit board, and the bottom surface of the second sub-die pad 1012 is electrically connected to an analog ground layer of the printed circuit board.

In some embodiments of the present disclosure, the die 107 is a 10G Ethernet physical layer integrated circuit die. It should be noted that the die 107 may also be a die performing other functions, which is not limited in the present disclosure.

In some embodiments of the present disclosure, the packaged chip 100 has 68 leads: leads 1 to 68, and the packaged chip 100 has a size of 8 mm×8 mm.

In some embodiments of the present disclosure, the die 107 has a plurality of bond pads 201. The plurality of bond pads 201 include a plurality of digital bond pads 2011 and a plurality of analog bond pads 2012. The plurality of digital bond pads 2011 include ground bond pads 20111, power bond pads 20112 and signal bond pads 20113. The ground bond pads 20111 are also called digital ground bond pads of the die 107, the power bond pads 20112 are also called digital power bond pads of the die 107, and the signal bond pads 20113 are also called digital signal bond pads of the die 107.

The plurality of analog bond pads 2012 include ground bond pads 20121, power bond pads 20122 and signal bond pads 20123. The ground bond pads 20121 are also called analog ground bond pads of the die 107, the power bond pads 20122 are also called analog power bond pads of the die 107, and the signal bond pads 20123 are also called analog signal bond pads of the die 107.

Referring to FIG. 1, in some embodiments of the present disclosure, the packaged chip 100 further includes a first ground bar 103 and a second ground bar 104. The first ground bar 103 is configured to be electrically connected with the first sub-die pad 1011, so that the first ground bar 103 and the first sub-die pad 1011 are equipotential. The second ground bar 104 is configured to be electrically connected with the second sub-die pad 1012, so that the second ground bar 104 and the second sub-die pad 1012 are equipotential.

Besides, the first ground bar 103 and the second ground bar 104 may be located above the die pad 101 or around the die pad 101 (as shown in FIG. 1). The first ground bar 103 may be electrically connected to the bottom surface of the first sub-die pad 1011 through a conductive material (such as a conductive epoxy). The conductive material is arranged between the first ground bar 103 and the bottom surface of the first sub-die pad 1011. The second ground bar 104 may be electrically connected to the bottom surface of the second sub-die pad 1012 through a conductive material. The conductive material is arranged between the second ground bar 104 and the bottom surface of the second sub-die pad 1012.

It should be noted that although only the first ground bar 103 and the second ground bar 104 are disposed in the above embodiment, in practical application, a plurality of ground bars electrically connected to the first sub-die pad 1011 and the second sub-die pad 1012 may be respectively designed according to needs. The present disclosure does not limit the number of ground bars.

Referring to FIG. 1, as described above, the die 107 includes the plurality of digital bond pads 2011 and the plurality of analog bond pads 2012. In some embodiments of the present disclosure, the die pad 101 is divided into the first sub-die pad 1011 and the second sub-die pad 1012 by a trench 102 at a junction of the analog bond pads 2012 of the die 107 and the digital bond pads 2011 of the die 107.

In some embodiments of the present disclosure, the first ground bar 103 is configured to be located on a first side of the trench 102, and the second ground bar 104 is located on a second side of the trench 102. The first sub-die pad 1011 is located on the first side of the trench 102, and the second sub-die pad 1012 is located on the second side of the trench 102. Each of the digital ground bond pads (ground bond pads 20111) of the die 107 is connected with the first ground bar 103 through a bond wire, and each of the analog ground bond pads (ground bond pads 20121) of the die 107 is connected with the second ground bar 104 through a bond wire. In some embodiments of the present disclosure, the bond wire includes gold, copper or a combination thereof, or other suitable materials, which is not limited in the present disclosure.

Referring to FIG. 1 again, the die 107 is planned to include a plurality of power domains, and circuits located in different power domains correspond to different power sources, so as to allow the circuits in different power domains to use different power sources. In some embodiments of the present disclosure, corresponding to a power domain (referred to as a first power domain for convenience of description) in the power domains of the die 107, the packaged chip 100 includes at least one power bar connected with a plurality of leads corresponding to different positions of the first power domain, and each of a plurality of power bond pads corresponding to the first power domain is connected with the power bar through the bond wire.

For example, the lead 53 and the lead 57 (named DVDDL) are used to externally connect a power source for supplying power to a certain power domain of the die 107, the packaged chip 100 includes a power bar 105 connected with the lead 53 and the lead 57, and a power bond pad 301 and a power bond pad 302 on the die 107 corresponding to the certain power domain are respectively connected with the power bar 105 through a bond wire 303 and a bond wire 304.

In some embodiments of the present disclosure, the first power domain is a power domain in the plurality of power domains of the die 107 having a power consumption greater than a preset value. That is, a power domain in the plurality of power domains of the die 107 having a high power consumption may adopt the above power bar design. It should be noted that the design of connecting at least one power bar with the plurality of leads corresponding to different positions of the first power domain can increase bonding zones for the bond wires. With the increase of the bonding zones for the bond wires, the power bond pads (e.g., the power bond pads 20112 and the power bond pads 20122 in FIG. 1) on the die 107 do not need to be crowded in the same zone during position design and can be distributed uniformly, the number of the leads can be reduced, and the RLC effect is weak, so that good electrical properties and current resistance can be provided. With the increase of the bonding zones for the bond wires, the impedance can be reduced, so that the IR-drop is improved. In addition, due to the increase of the bonding zones for the bond wires, a low power impedance can be obtained.

Referring to FIG. 1 and FIG. 2 again, in some embodiments of the present disclosure, the packaged chip 100 includes a plurality of scattered power supply leads. In the embodiment shown in FIG. 1 and FIG. 2, the packaged chip 100 includes the scattered power supply leads: the lead 26, the lead 32, the lead 53 and the lead 57 (all named DVDDL). The power bar 105 is connected with the lead 53 and the lead 57, and the power bar 106 is connected with the lead 26 and the lead 32. The plurality of scattered power supply leads can alleviate the problems of RLC properties and IR-drop.

It should be noted that the packaged chip 100 may use low-profile quad flat package (LQFP), thin quad flat package (TQFP), quad flat non-leaded (QFN) package, dual flat no-lead (DFN) package, multi-zone quad flat non-leaded package, multi-die flip-chip package and other applicable package technologies.

Based on the above, according to the packaged chip provided by some embodiments of the present disclosure, by using the first sub-die pad 1011 as the digital ground of the packaged chip 100 and the second sub-die pad 1012 as the analog ground of the packaged chip 100, the interference between the grounds can be reduced. In some embodiments of the present disclosure, the design of connecting at least one power bar with the plurality of leads corresponding to different positions of the first power domain can increase bonding zones for the bond wires. With the increase of the bonding zones for the bond wires, the power bond pads on the die 107 do not need to be crowded in the same zone during position design and can be distributed uniformly, the number of the leads can be reduced, and the RLC effect is weak, so that good electrical properties and current resistance can be provided. With the increase of the bonding zones for the bond wires, the impedance can be reduced, so that the IR-drop is improved. In addition, due to the increase of the bonding zones for the bond wires, a low power impedance can be obtained. The packaged chip 100 in some embodiments of the present disclosure include the plurality of scattered power supply leads, so that the problems of RLC properties and IR-drop can be alleviated.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A packaged chip, comprising:
a die pad, comprising a first sub-die pad and a second sub-die pad; and
a die, disposed on the die pad,
wherein the first sub-die pad and the second sub-die pad are electrically isolated, the first sub-die pad serving as a digital ground and the second sub-die pad serving as an analog ground.

2. The packaged chip according to claim 1, wherein the die is a 10G Ethernet physical layer integrated circuit die.

3. The packaged chip according to claim 1, wherein the packaged chip is packaged by a package process, and the packaged chip has 68 leads and a size of 8 mm ×8 mm.

4. The packaged chip according to claim 3, wherein the package process is selected from the group consisting of a low-profile quad flat package process, a thin quad flat package process, a quad flat non-leaded package process, a dual flat no-lead process, a multi-zone quad flat non-leaded package process and a multi-die flip-chip package process.

5. The packaged chip according to claim 1, wherein the packaged chip comprises:
a first ground bar, configured to be electrically connected with the first sub-die pad, the first ground bar and the first sub-die pad being equipotential; and
a second ground bar, configured to be electrically connected with the second sub-die pad, the second ground bar and the second sub-die pad being equipotential.

6. The packaged chip according to claim 1, wherein a bottom surface of the first sub-die pad is exposed outside a molding compound of the packaged chip, and a bottom surface of the second sub-die pad is exposed outside the molding compound of the packaged chip.

7. The packaged chip according to claim 1, wherein the die comprises a plurality of analog bond pads and a plurality of digital bond pads, and the die pad is divided into the first sub-die pad and the second sub-die pad by a trench at a junction of the analog bond pads of the die and the digital bond pads of the die.

8. The packaged chip according to claim 7, wherein the packaged chip comprises:
a first ground bar, configured to be electrically connected with the first sub-die pad, the first ground bar and the first sub-die pad being equipotential; and
a second ground bar, configured to be electrically connected with the second sub-die pad, the second ground bar and the second sub-die pad being equipotential, wherein the first ground bar is configured to be located on a first side of the trench, and the second ground bar is located on a second side of the trench.

9. The packaged chip according to claim 8, wherein the die comprises a plurality of ground bond pads, the ground bond pads comprising a plurality of analog ground bond pads and a plurality of digital ground bond pads, each of the digital ground bond pads being connected with the first ground bar through a bond wire, and each of the analog ground bond pads being connected with the second ground bar through a bond wire.

10. The packaged chip according to claim 1, wherein the die comprises a plurality of power domains, corresponding to a first power domain in the power domains of the die, the packaged chip comprises at least one power bar connected with a plurality of leads corresponding to different positions of the first power domain, and each of a plurality of power bond pads corresponding to the first power domain is connected with the power bar through a bond wire.

11. The packaged chip according to claim 10, wherein a power consumption of the first power domain is greater than a preset value.

12. The packaged chip according to claim 1, wherein the packaged chip comprises a plurality of scattered power supply leads.
